(19) United States
(12) Patent Application Publication
(10) Pub. No.: US 2009/0120364 A1
(43) Pub. Date: May 14, 2009

(54) GAS MIXING SWIRL INSERT ASSEMBLY

(75) Inventors: Edwin C. Suarez, Fremont, CA (US); Karthik Janakiraman, San Jose, CA (US); Paul Edward Gee, San Jose, CA (US)

Correspondence Address: TOWNSEND AND TOWNSEND AND CREW LLP, TWO EMBARCADERO CENTER, EIGHTH FLOOR, SAN FRANCISCO, CA, 94111-3834, US

(73) Assignee: Applied Materials, Inc., Santa Clara, CA (US)

(21) Appl. No.: 12/251,323

(22) Filed: Oct. 14, 2008

Related U.S. Application Data
(60) Provisional application No. 60/986,923, filed on Nov. 9, 2007.

(51) Int. Cl. C23C 16/455; B67D 5/56; B05B 1/34

(52) U.S. Cl. 118/715; 118/726; 137/896; 239/399; 239/432

(57) ABSTRACT

A gas mixing system for a semiconductor wafer processing chamber is described. The mixing system may include a gas mixing chamber concentrically aligned with a gas transport tube that extends to a blocker plate. The gas mixing chamber and the transport tube are separated by a porous barrier that increases a duration of gas mixing in the gas mixing chamber before processes gases migrate into the transport tube. The system may also include a gas mixing insert having a top section with a first diameter and a second section with a second diameter smaller than the first diameter and concentrically aligned with the top section. The processes gases enter the top section of the insert and follow channels through the second section that cause the gases to mix and swirl in the gas mixing chamber. The second section extends into the gas mixing chamber while still leaving space for the mixing and swirling around the sidewalls and bottom of the mixing chamber.

### CROSS-REFERENCES TO RELATED APPLICATIONS

The present application claims benefit under 35 USC 119(e) of U.S. provisional Application No. 60/986,923, filed on Nov. 9, 2007, entitled “GAS MIXING SWIRL INSERT ASSEMBLY,” the entire content of which is incorporated herein by reference for all purposes.

This application also relates to U.S. Pat. Nos. 6,068,703 and 6,303,501 to Chen et al, both of which are titled “Gas Mixing Apparatus and Method.” The entire contents of both patents are herein incorporated by reference for all purposes.

### BACKGROUND OF THE INVENTION

Semiconductor device geometries have dramatically decreased in size since such devices were first introduced several decades ago. Today's wafer fabrication plants are routinely producing sub-100 nm feature size devices, and tomorrow's plants soon will be producing devices having even smaller feature sizes.

One of the primary steps in fabricating modern semiconductor devices involves the formation of a dielectric, metal, or insulating layers over a semiconductor substrate. As is well known, such layers can be deposited by chemical vapor deposition (CVD). CVD processes are particularly suitable for use with high integration devices because CVD layers provide superior step coverage and post-annealing qualities to those layers formed by sputtering or other conventional deposition methods. In a conventional thermal CVD process, reactive gases are supplied to the substrate surface where heat-induced chemical reactions (homogeneous or heterogeneous) take place to produce a desired film. In a plasma enhanced chemical vapor deposition (PECVD) process, the flowing gas may be excited to a plasma state. A controlled plasma is formed to decompose and/or energize reactive species to produce the desired film. The process of depositing layers on a semiconductor wafer (or substrate) usually involves heating the substrate and holding it a short distance from the source of a stream of deposition (or process) gas flowing towards the substrate. In general, reaction rates in thermal and plasma processes may be controlled by controlling one or more of the following: temperature, pressure, and reactant gas characteristics.

In the quest to achieve ever smaller devices, increasingly stringent process requirements are being imposed on integrated device manufacturing processes. One such requirement is the thorough mixture of process gases prior to introduction of the gases into a CVD chamber. A thorough mixture of the process gases is typically necessary to achieve a uniform deposition pattern on the semiconductor substrate. If the quality of the mixing achieved by the plurality of gases is insufficient, the CVD process using the gases will provide an uneven deposition pattern, which may result in variance of the sheet resistance of the deposited film, delamination during annealing, or other undesirable qualities which may degrade device performance.

Unfortunately, CVD processes are becoming more sensitive to gas flow and mixture parameters as device sizes shrink and device performance increases. Conventional gas mixers adapted to provide adequate levels of gas mixing are costly to manufacture and sensitive to minor flaws associated with manufacturing. Conventional mixers typically only use one mixing step and rely on a mixer that is difficult to test prior to actual use in a semiconductor system. Hence, it would be desirable to provide an improved gas mixing apparatus that would provide reliable and thorough gas mixing. These issues and others are addressed by the present invention.

### BRIEF SUMMARY OF THE INVENTION

Gas mixing equipment is describe to homogenously mix process gases before they enter a reaction zone of a semiconductor processing chamber. The equipment includes a gas mixing insert with fluid channels shaped and oriented to cause the process gases flowing through it to collide and mix after leaving the insert. The mixing space around the insert is also partially enclosed to enhance the extent of mixing before the mixed gas escapes into a conduit that supplies gas to the showerhead or gas nozzles for distribution into the reaction zone.

Embodiments of the invention include a gas mixing system for use with a semiconductor wafer processing chamber. The mixing system may include a gas mixing chamber concentrically aligned with a gas transport tube that extends to a blocker plate. The gas mixing chamber and the transport tube are separated by a porous barrier that increases a duration of gas mixing in the gas mixing chamber before processes gases migrate into the transport tube. The system may also include a gas mixing insert having a top section with a first diameter and a second section with a second diameter smaller than the first diameter and concentrically aligned with the top section. The processes gases enter the top section of the insert and follow channels through the second section that cause the gases to mix and swirl in the gas mixing chamber. The second section extends into the gas mixing chamber while still leaving space for the mixing and swirling around the sidewalls and bottom of the mixing chamber.

Embodiments of the invention also include a gas mixing apparatus used in a semiconductor processing chamber. The mixing apparatus may include a gas mixing chamber comprising a gas inlet to receive process gases, a gas outlet to flow mixed gas out of the chamber, and an insert recess. The apparatus may also include a gas mixing insert slidably fitted within the insert recess, and a fluid flow channel at least part of which is formed in the gas mixing insert, and fluidly coupled to the gas inlet. The fluid flow channel includes one or more fluid separators, each comprising a first carrier channel having a channel surface separating the process gases into a plurality of gas portions flowing away from each other in the channel. A fluid collection space is formed between the gas mixing insert and the periphery of the gas mixing chamber. The separated gas portions exiting the fluid separators approach from substantially opposite directions and collide with each other to combine the gas portions into the mixed gas. The apparatus may further include a gas transport conduit to receive the mixed gas from the gas outlet and further mix and transport the mixed gas to a blocker plate of a showerhead.

Embodiments of the invention also include a semiconductor fabrication processing chamber with a gas mixing system. The chamber may include an enclosure housing a processing chamber with a process gas inlet, a gas supply line fluidly coupled to the process gas inlet, and a support disposed within the processing chamber and having a support surface for supporting a semiconductor wafer. The chamber may also include a gas manifold fluidly coupled to the process gas inlet to distribute process gases across the semiconductor wafer, and a gas mixing apparatus fluidly coupled between the process gas inlet and the gas manifold. The gas mixing apparatus may include a gas mixing chamber concentrically aligned with a gas transport tube that extends to the gas manifold, where the gas mixing chamber and the transport tube are separated by a porous barrier that increases a duration of gas mixing in the gas mixing chamber before processes gases migrate into the transport tube. In addition the gas mixing apparatus may include a gas mixing insert having a top section with a first diameter and a second section with a second diameter smaller than the first diameter and concentrically aligned with the top section. The processes gases enter the top section of the insert and follow channels through the second section that cause the gases to mix and swirl in the gas mixing chamber. The second section extends into the gas mixing chamber while still leaving space for the mixing and swirling around the sidewalls and bottom of the mixing chamber.

Embodiments of the invention further include a gas swirl mixing device for semiconductor processing chamber. The mixing device may include a transport plate having a plurality of holes with a first angle to guide a mixture of process gases to flow through the holes toward a first direction. The mixing device may also include a transport tube having a plurality of holes with a second angle near bottom of the transport tube, wherein the holes are connected to a recess on an inner sidewall of the transport tube to guide the mixture to flow toward a second direction, where the second direction is opposite to the first direction, and the second angle is different from the first angle. The mixing device also includes a mixing chamber concentrically aligned with the transport tube, where the plate is coupled to the transport tube that is coupled to the mixing chamber to prevent a secondary process gas path.

Embodiments of the invention also include a chamber system for semiconductor processing. The system includes a processing chamber, a first substrate supporting member to support a first substrate within the processing chamber, a second substrate supporting member to support a second substrate, where the second substrate supporting member is positioned near the first substrate supporting member within the processing chamber. The system also includes a first swirl mixing device being located above the first substrate supporting member for providing mixed flow of process gases toward the first substrate. The system further includes a second swirl mixing device located above the second substrate supporting member for providing mixed flow of process gases toward the second substrate; where a first flow direction generated from a first transport tube of the first swirling mixing device being opposite to a second flow direction generated from a second transport tube of the second swirling mixing device.

Additional embodiments and features are set forth in part in the description that follows, and in part will become apparent to those skilled in the art upon examination of the specification or may be learned by the practice of the invention. The features and advantages of the invention may be realized and attained by means of the instrumentalities, combinations, and methods described in the specification.

### BRIEF DESCRIPTION OF THE DRAWINGS

A further understanding of the nature and advantages of the present invention may be realized by reference to the remaining portions of the specification and the drawings and appendix wherein like reference numerals are used throughout the several drawings to refer to similar components. In some instances, a sub-label is associated with a reference numeral and follows a hyphen to denote one of multiple similar components. When reference is made to a reference numeral without specification to an existing sublabel, it is intended to refer to all such multiple similar components.

FIG. 1A shows a cross-sectional view of standard mixing insert design (prior art).

FIG. 1B shows a cross-sectional view of swirl mixing insert design according to embodiments of the invention.

FIG. 2A shows a first assembly of swirling mixing inserts according to the embodiment of the invention.

FIG. 2B shows a second assembly of swirling mixing inserts according to embodiments of the invention.

FIGS. 3A-3B are plots of thickness uniformity for the first assembly of swirl mixing inserts shown in FIG. 2A and the second assembly of swirl mixing inserts shown in FIG. 2B, respectively.

FIG. 4 is a simplified schematic of an automatic flow splitter according to embodiments of the invention.

FIG. 5 is a plot of thickness vs motor step for a micrometer shown in FIG. 4.

FIG. 6 is a simplified schematic of a dual-pressure heater lift according to embodiments of the invention.

FIG. 7 includes plots of thickness uniformity versus compressed dry air (CDA) pressure in the Pneumatic cylinder as shown in FIG. 6.

### DETAILED DESCRIPTION OF THE INVENTION

Chamber Left-to-Right matching issues for dielectric film depositions in processing, such as a two-step boron-phosphate silicate glass (BPSG) deposition within a sub-atmospheric chemical vapor deposition (SACVD) chamber, may cause significant wafer side-to-side variation in thickness. This uneven side-to-side matching may be caused by multiple factors, such as variation in gas mixing, uneven delivery of gas/vapor, and heater leveling or lift to sides. These problems may be addressed with swirl mixing inserts, automatic flow splitters, and/or dual-pressure heater lifts designed for thorough gas mixing and uniform distribution in vapor delivery, as well as accurate spacing in heater leveling.

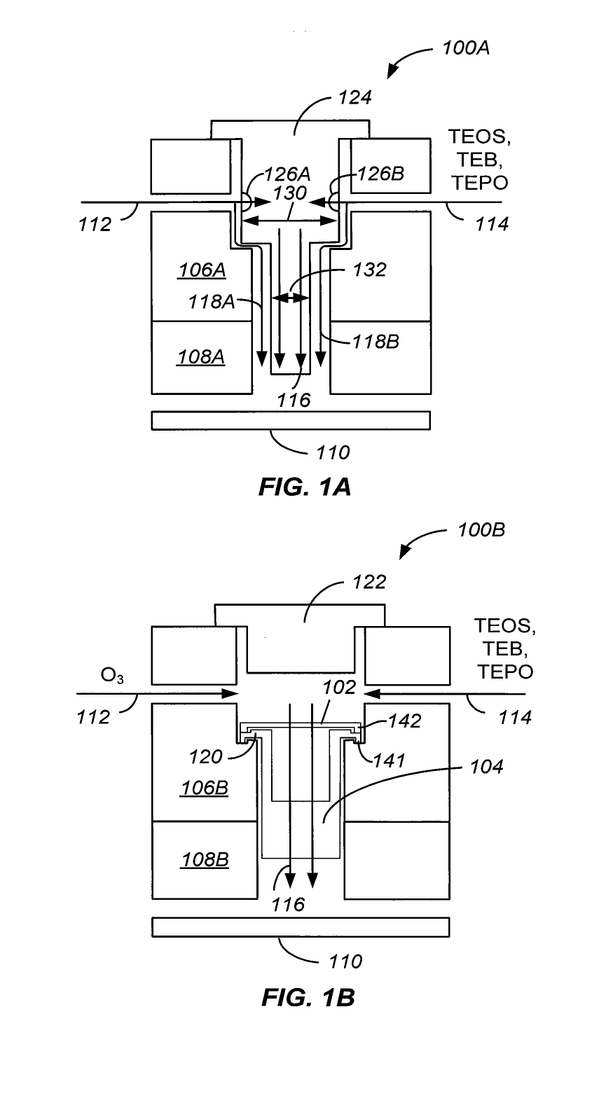

FIG. 1A illustrates a cross-sectional view of a standard mixing insert. The standard mixing insert 100A includes a mixing block 106A coupled to a gas box 108A, a mixing insert 124, and a blocker plate 110. A first process gas such as O₃ may flow into the mixing block 106A from a pipeline 112 and enter into a mixing insert 124 through an inlet 126A. On the other hand, a second process gas such as TEOS may flow into the mixing block 106A from a pipeline 114 and enter into the mixing insert 124 through an inlet 126B. The first and second process gases get mixed in the mixing insert 124 and flow down toward the blocker plate 110 as pointed by arrow 116. The blocker plate is positioned below the mixing block 106B and the transport tube 104.

The mixing insert 124 and the mixing block 206A may be of cylindrical shape. External diameters 130, 132 of the mixing insert 124 are smaller than inner diameters of the mixing block 106A. Therefore, a gap is formed between an inner sidewall of the mixing block 106A and an external sidewall of the standard mixing insert 124 to provide a secondary gas flow path as pointed by arrows 118A and 118B. As shown in FIG. 1A, the mixture of the first gas and second gas flow through the mixing insert 124 as pointed by arrow 116. However, some of the first gas from the pipeline 112 may flow through the gap as pointed by arrow 118A, while some of the second gas from the pipeline 114 may flow through the gap as pointed by arrow 118B.

FIG. 1B illustrates a cross-sectional view of a swirling mixing insert according to the embodiment of the invention. The swirling mixing insert 100B includes a mixing block 106B coupled to a gas box 108B, a mixing plate 102, a transport tube 104, a top cover 122, and a blocker plate 110. A first process gas such as O₃ may flow into the mixing block 106B from the pipeline 112, while a second process gas such as TEOS may flow into the mixing block 106B from the pipeline 114. The first and second gases flow through the mixing plate 102 and get mixed in the transport tube 204 and flow toward the blocker plate 110 as pointed by arrow 116.

The transport tube 104 may have a collared end 120 that has an external diameter approximately equal to an external diameter of the mixing plate 102. An external diameter of the transport tube 104 is approximately equal to an inner diameter of the mixing block 106B. The mixing block 106B, the mixing plate 102, the transport tube 104 may be made of a metal, such as aluminum.

Referring to FIG. 1B again, the mixing plate 102 contacts the collared end 120 of the transport tube 104 at a spot 142 that contacts the mixing block 106B at a spot 140. Therefore, a metal-to-metal contact is formed between the mixing plate 102 and the collared end 120 of the transport tube 104. Also, a metal-to-metal contact is formed between the transport tube 104 and the mixing block 106B. Such metal-to-metal contacts help prevent a secondary gas path 118 as shown in FIG. 1A for the standard mixing insert 100A.

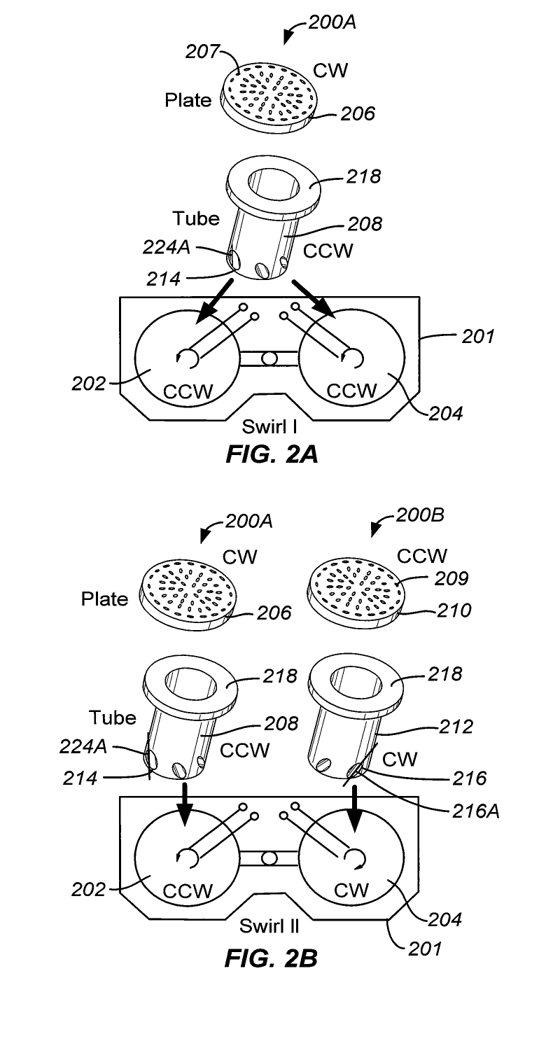

According to embodiments of the invention, the prevention of the secondary gas path helps improve mixing uniformity of process gases. The prevention of secondary gas path may also provide even splitting of the gas delivery to a first substrate 202 and a second substrate 204 as shown in FIGS. 2A & 2B.

FIGS. 2A and 2B show exploded views of swirl mixing insert assemblies (200A and 200B, respectively) to mix reactive gases that are introduced to exposed surfaces of substrates 202 and 204 in a dual-wafer processing chamber 201. FIG. 2A shows a swirl mixing insert assembly 200A, positioned above each of the substrate 202 and 204 in the processing chamber 201. Assembly 200A may include a mixing plate 206 placed over a collared end 218 of a transport tube 208. The circular mixing plate 206 includes a plurality of holes 207 extending through the thickness of the plate 206 that are shaped and oriented to direct gas flow in a first direction (e.g., a clockwise direction).

The process gases flow through a set of holes 214 formed through the sidewall of the transport tube 208 near the tube end opposite the collared end 218. The set of holes 214 formed in the transport tube 208 have an orientation 224A designed to direct the flow of the process gases in a second direction (e.g., a counterclockwise direction) that is opposite to the first direction. Mixing gases may be enhanced by entering the mixture of gases into the transport tube 208 in a first direction and exiting the mixture of gases from the transport tube 208 in a second direction that is opposite to the first direction. Such enhanced mixing may form a substantially uniform reactive gas mixture that supplies the reactants (e.g., ozone and TEOS) for a chemical vapor deposition of a dielectric film (e.g., a BPSG film) on the exposed surfaces of substrates 202 and 204.

In FIG. 2A the dominant flow direction of the mixed gases is the direction of the second process gas flowing through holes 214 (e.g., CCW). Because the dual-wafer process chamber uses a pair of swirl mixing insert assemblies 210A to mix the gases above each of the substrates 202 and 204, both substrates are exposed to a mixed gas flowing in the same direction (e.g., CCW). This can create an asymmetrical flow path for the pair of mixed gases that can result in differences in the deposition uniformity for each of the substrates 202 and 204. For example, when both sets of mixed gases are circulating in a counterclockwise direction above the substrates, the dielectric film deposited on substrate 202 may have a higher uniformity than the film deposited on substrate 204.

FIG. 2B shows the dual wafer processing chamber 201 using the swirl mixing insert assembly 200A to provide a mixed gas to one substrate 202, while using swirl mixing insert assembly 200B for the second substrate 204. The two assemblies 200A & 200B are designed to provide mixed gases with different flow directions. In the example shown in FIG. 2B, the mixed gases exiting the assemblies 200A & 200B flow in opposite directions (e.g., CCW versus CW) to provide a symmetric flow of gases over substrates 202 and 204. This provides a similar uniformity of the deposited dielectric films (e.g., a BPSG film) over both substrates.

The assembly 200B may include a mixing plate 210 placed over the collared end 218 of a transport tube 212. The circular mixing plate 210 includes a plurality of holes 209 extending through the thickness of the plate that are shaped and oriented to direct process gases in the second direction (e.g. CCW) that is opposite to the first direction (e.g. CW) generated by the mixing plate 206 of assembly 200A. The holes 209 are different from the holes 207 of assembly 200A. The mixture of the first and second gas flows into the transport tube 212 through the set of holes 209 and exits the transport tube 212 through a set of holes 216 that have an orientation 216A designed to direct the gas flow in the first direction (e.g. CW). As noted above the example shown in FIG. 2B has the mixed gases emerging from assemblies 200A & B circulating in opposite directions (e.g., CCW versus CW).

The mixing plate 102 as shown in FIG. 1B may be the mixing plate 106 (CW) of the first assembly 200A or plate 110 (CCW) of the second assembly 200B as shown in FIG. 2A and 2B, while the transport tube 104 as shown in FIG. 1B may be the transport tube 208 (CCW) of the first assembly 200A or the transport tube 212 (CW) of the second assembly 200B.

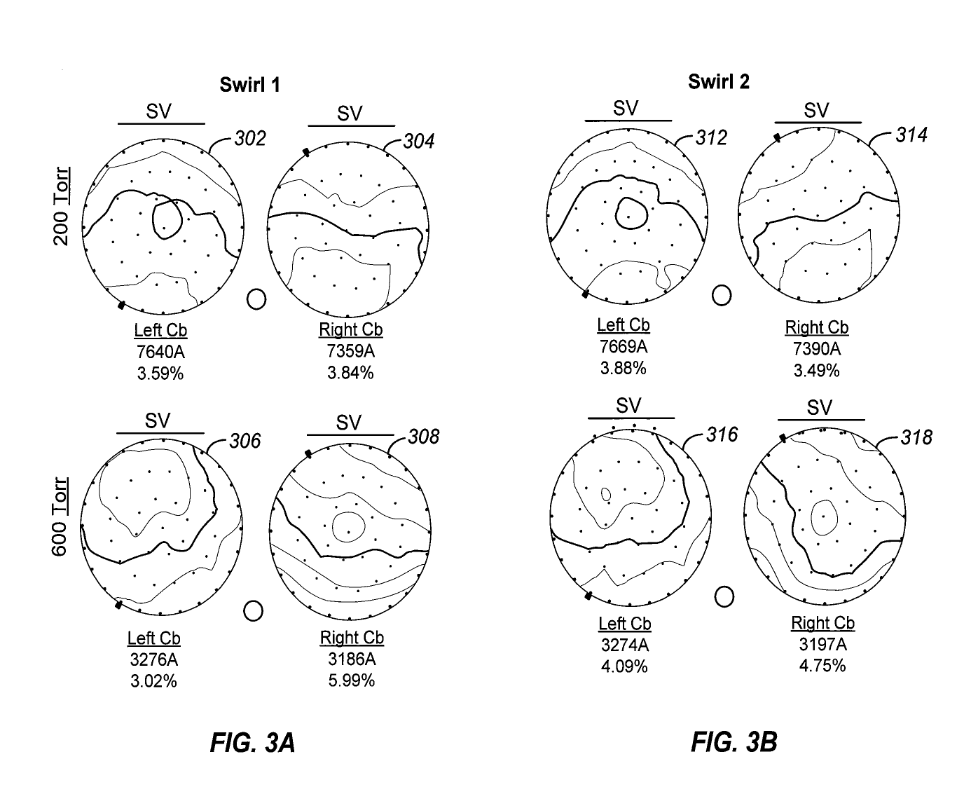

Extensive experiments have been performed by using the first assembly 200A, the second assembly 200B of swirl mixing inserts, Automatic Flow Splitter, and Dual-Pressure Heater Lift mechanism. FIG. 3A shows the thickness maps for the substrate 204 at two pressures 200 torr and 600 torr by using the first assembly 200A of swirl mixing inserts, where a thickness map 302 is for the substrate 202 or left side at 200 torr, a thickness map 304 for the substrate 204 or right side at 200 torr, a thickness map 306 for the substrate 202 at 600 torr, and a thickness map 308 for the substrate 204 at 600 torr.

A thickness uniformity is defined by:

Thickness Uniformity=(maximum thickness-minimum thickness)/average thickness/2%

In FIG. 3A, note that the thickness uniformity is 5.99% for the thickness map 308, which is significantly higher than for the other three thickness maps 302, 304 and 306 (ranging from 3.59% to 3.84%).

FIG. 3B shows the thickness maps for substrate 204 at two pressures 200 torr and 600 torr by using the second assembly 200B of swirl mixing inserts according to the embodiments of the invention, where a thickness map 312 is for the substrate 202 or left side at 200 torr, a thickness map 314 for the substrate 204 or right side at 200 torr, a thickness map 316 for the substrate 202 at 600 torr, and a thickness map 318 for the substrate 204 at 600 torr. Note that the thickness uniformity is reduced to 4.75% for the thickness map 318 from 5.99%, and is closer to the ranges for the other three thickness maps 302, 304 and 306 (ranging from 3.49% to 4.09%).

Results show that the thickness variation on both substrate 202 and substrate 204 have been reduced when using the second assembly 200B of swirl mixing inserts to replace the first assembly 200A of swirl mixing inserts. The second assembly 200B allows uniform mixing for both substrates 202 and 204, and improves thickness uniformity for substrate 204 from 6% to 4.75%.

Processing gas/vapor may not be distributed evenly to chamber substrates 202 and 204 for 2-step BPSG due to different conductance in gas delivery hardware. As more gas flow results in thicker film, thickness may not be matched on the substrates 202 and 204. In another set of the embodiments, Automatic Flow Splitter is designed with motorized micrometers that can be used to adjust conductance of process gas flow to the substrate 204 and substrate 204 to match thickness uniformity for both substrates 202 and 204. This Automatic Flow Splitter helps solve the thickness match issue as described above.

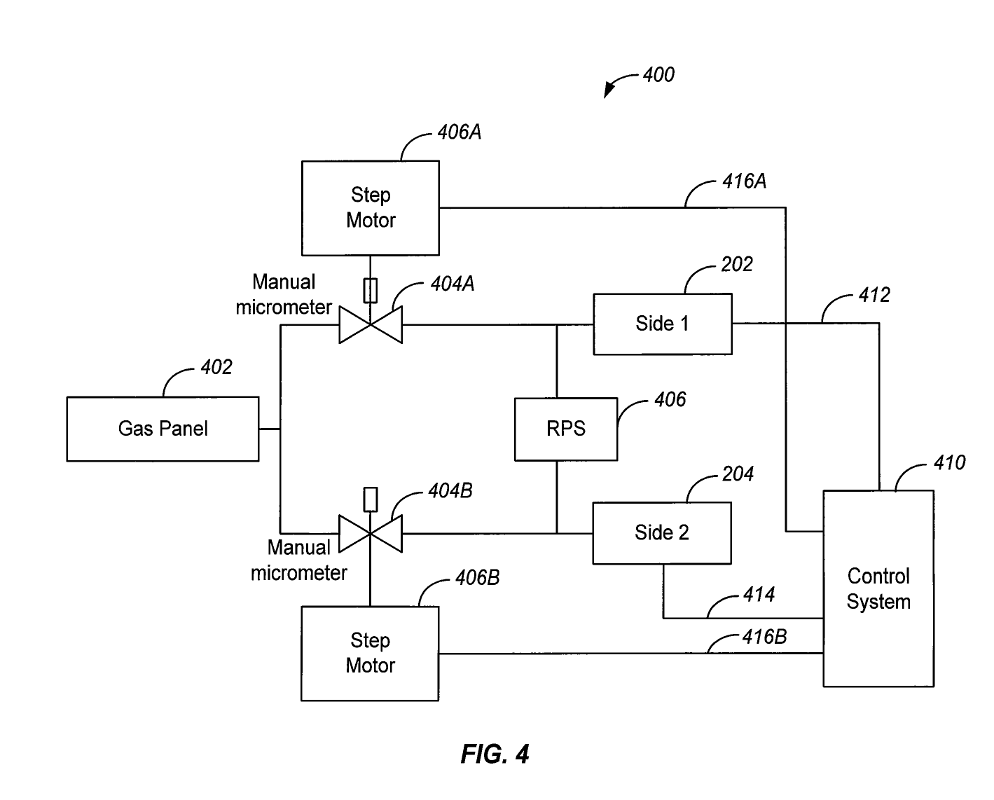

FIG. 4 illustrates a simplified schematic for an Automatic Flow Splitter. The Automatic Flow Splitter 400 includes a gas panel 402, two step motors 406A and 406B, two micrometers 404A and 404B for adjusting conductance of gas flow through valve openings, a remote plasma source 408, and a controller system with software 410. The controller system 410 may determine how to adjust the step motors 406A and 406B. The two step motors 406A and 406B can then adjust the two micrometers 404A and 404B in order to change the relative gas delivery to the substrates 202 and 204 for balancing the thickness on the two substrates 202 and 204. There may be 1500 steps for the motors 406A and 406B, each step is at 260 mils.

In a specific embodiment, when the thickness on the substrate 202 is thinner than the substrate 204, a signal may be sent from substrates 202 and 204 through communication lines 412 and 414 to the controller system 410. The controller system 410 may send signals through lines 416A and 416B to the step motors 406A and 406B to adjust the micrometers 404A and 404B to increase the gas flow from gas panel 402 to the substrate 204 and decrease the flow to the substrate 204.

In an alternative embodiment, when the thickness on substrate 202 is thicker than the substrate 204, a signal may be sent from substrates 202 and 204 through the communication lines 412 and 414 to the controller system 410. The controller system 410 may send signals through the communication lines 416A and 416B to the step motors 406A and 406B to adjust the micrometers 404A and 404B to decrease the gas flow from gas panel 402 to the substrate 204 and increase the flow to the substrate 204.

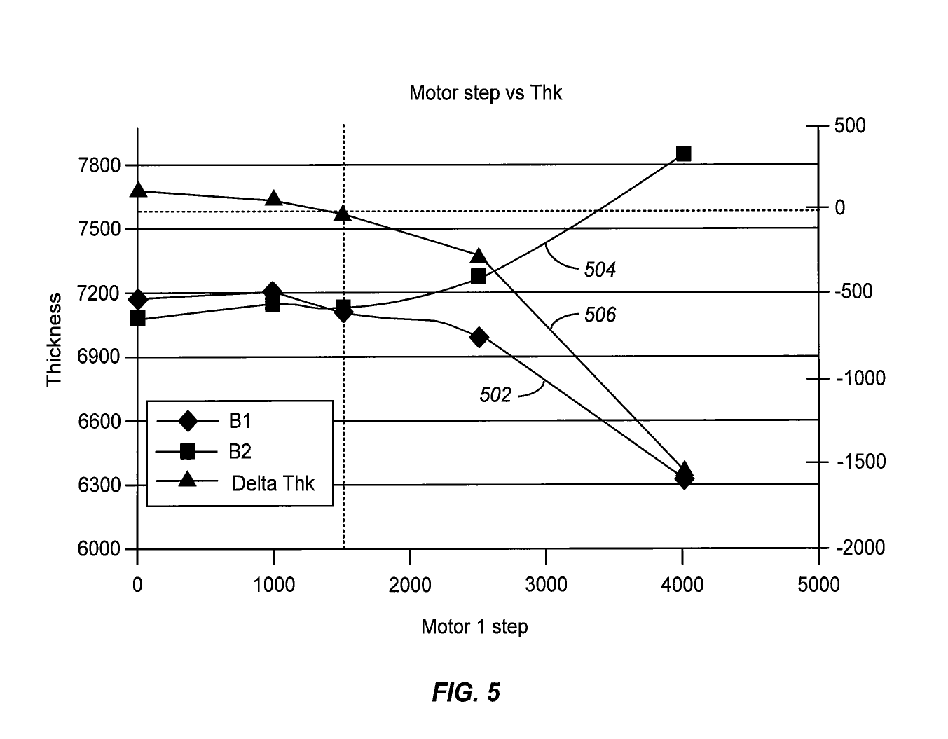

Inventors have performed extensive experiments by using the Automatic Flow Splitter 400. FIG. 5 demonstrates the effect of motor step on thickness. Note that curve 502 is thickness for the substrate 204 versus motor step for the step motor 406A, curve 504 is thickness for the substrate 204 versus motor step for the step motor 406A, and curve 506 is delta thickness between curve 502 and curve 504 with negative values as shown in the vertical axis on the right side of FIG. 5. When the motor step for the step motor 406A increases, the micrometer 404A is adjusted to decrease the gas flow to the substrate 204 so that the thickness decreases on the substrate 204 as shown by curve 502, while the thickness on the substrate 204 increases as shown by curve 504. The change in thickness on the substrate 204 is substantially linear to the change in thickness on the substrate 204. This example demonstrates that Automatic Flow Splitter design 400 adjusts conductance of process gas flow, and matches thickness uniformity of both substrates 202 and 204 at 1500 steps from fully open.

For a 2-step SACVD BPSG process with chamber pressure requirement of 200 Torr and 600 Torr, a heater is usually leveled at a chamber pressure of 200 Torr. In case of depositing a multiple stacks of films, chamber pressure may be changed. For example, a chamber pressure of 600 Torr may be used to achieve a relatively low deposition rate, while a chamber pressure of 200 Torr may be used to achieve a relatively higher deposition rate. Parallelism between heater surface and faceplate are often leveled at 200 Torr. When the chamber pressure is changed to 600 Torr, the parallelism between heater surface and faceplate is altered due to the chamber pressure change. This problem may be resolved by using a Dual-Pressure Heater Lift design.

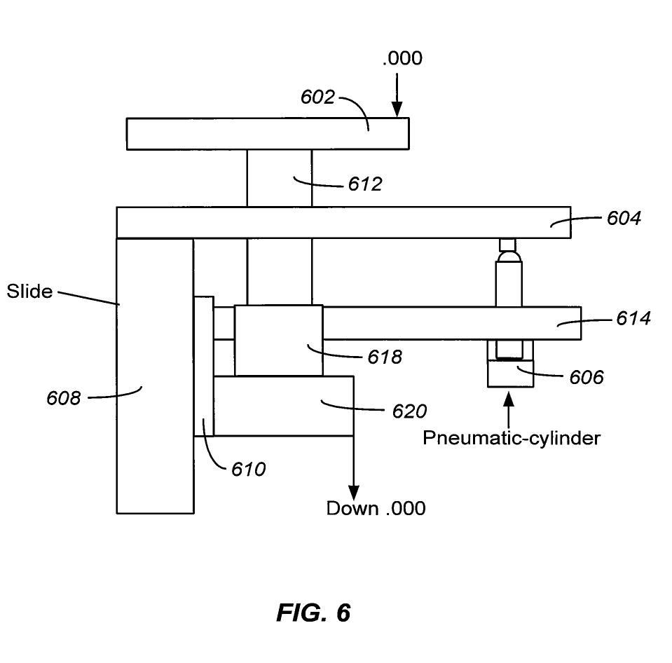

FIG. 6 shows a schematic of a Dual-Pressure Heater Lift design 600, including a heater 602, a cantilever 604, a pneumatic cylinder 606, a main frame 608 that supports the cantilever 604, the heater 602 through a support member 612. The Dual-Pressure Heater Lift design 600 also includes a slider 610 that is coupled to the main frame 608. The pneumatic cylinder 606 and the main frame 608 as well as the supporting member 612 are attached to a carrier member 614. A carrier 620 is coupled to the slider 610 and the support member 612 through a hub 618 that is coupled to the carrier member 614. The pneumatic cylinder 606 would provide a CDA pressure to lift the cantilever 604. For example, when the chamber pressure is changed from 200 Torr to 600 Torr or other pressure, a pressure is pressed against the heater 602 to generate a downward movement in the slider 610 to cause the tilting of the heater 602. A CDR from the Pneumatic cylinder may be provided to lift the heater 602 to adjust the spacing between the heater and a faceplate or showerhead (not shown) above the heater.

One benefit of the Dual-Pressure Heater Lift design 600 is to allow the cantilever 604 to be lifted by Pneumatic pressure to counterbalance the effect of chamber pressure change from 200 Torr to 600 Torr. The Dual-Pressure Heater Lift design 600 incorporates the pneumatic cylinder 606 at an end of the cantilever 604 to counter balance additional force from chamber pressure difference of 400 Torr.

In a further embodiment of the invention, different compressed dry air (CDA) pressures may be required for balancing heater lift of the substrates 202 and 204 to resolve the side-to-side matching issue, as geometrical tolerances may introduce inconsistency to heater surface tilting.

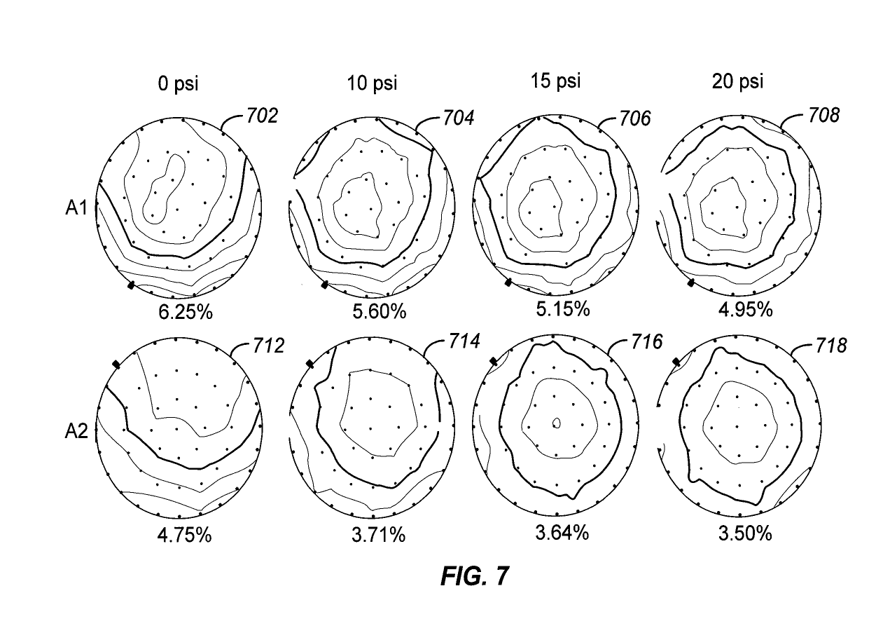

Inventors have performed experiments to demonstrate that Dual-Pressure Heater Lift design 600 accommodates heater tilting at 600 Torr and improves thickness uniformity. FIG. 7 show multiple thickness maps for multiple stacks of films, including a first set of thickness maps 702, 704, 706 and 708 for substrate 204 (left side) at CDA pressures of 0 psi, 10 psi, 15 psi and 20 psi, respectively, and a second set of thickness maps 712, 714, 716, and 718 for substrate 204 (right side) at CDA pressures of 0 psi, 10 psi, 15 psi and 20 psi, respectively. Note that the thickness uniformity decreases from 6.25% to 4.95% for the substrate 204 with increasing CDA pressure from 0 psi to 20 psi. The thickness uniformity also decreases from 4.75% to 3.5% with increasing CDA pressure from 0 psi to 20 psi.

Having described several embodiments, it will be recognized by those of skill in the art that various modifications, alternative constructions, and equivalents may be used without departing from the spirit of the invention. Additionally, a number of well-known processes and elements have not been described in order to avoid unnecessarily obscuring the present invention. Accordingly, the above description should not be taken as limiting the scope of the invention.

Where a range of values is provided, it is understood that each intervening value, to the tenth of the unit of the lower limit unless the context clearly dictates otherwise, between the upper and lower limits of that range is also specifically disclosed. Each smaller range between any stated value or intervening value in a stated range and any other stated or intervening value in that stated range is encompassed. The upper and lower limits of these smaller ranges may independently be included or excluded in the range, and each range where either, neither or both limits are included in the smaller ranges is also encompassed within the invention, subject to any specifically excluded limit in the stated range. Where the stated range includes one or both of the limits, ranges excluding either or both of those included limits are also included.

As used herein and in the appended claims, the singular forms “a”, “an”, and “the” include plural referents unless the context clearly dictates otherwise. Thus, for example, reference to “a process” includes a plurality of such processes and reference to “the channel” includes reference to one or more channels and equivalents thereof known to those skilled in the art, and so forth.

Also, the words “comprise,” “comprising,” “include,” “including,” and “includes” when used in this specification and in the following claims are intended to specify the presence of stated features, integers, components, or steps, but they do not preclude the presence or addition of one or more other features, integers, components, steps, acts, or groups.

What is claimed is:

1. A gas mixing system for use with a semiconductor wafer processing chamber, the mixing system comprising:
a gas mixing chamber concentrically aligned with a gas transport tube that extends to a blocker plate, wherein the gas mixing chamber and the transport tube are separated by a porous barrier that increases a duration of gas mixing in the gas mixing chamber before processes gases migrate into the transport tube;
a gas mixing insert having a top section with a first diameter and a second section with a second diameter smaller than the first diameter and concentrically aligned with the top section, wherein the processes gases enter the top section of the insert and follow channels through the second section that cause the gases to mix and swirl in the gas mixing chamber, and wherein the second section extends into the gas mixing chamber while still leaving space for the mixing and swirling around the sidewalls and bottom of the mixing chamber.

2. The gas mixing system of claim 1, wherein the blocker plate comprises part of a gas showerhead that also includes a faceplate below the blocker plate.

3. The gas mixing system of claim 1, wherein the top and second sections of the gas mixing insert are both cylindrically shaped.

4. The gas mixing system of claim 3, wherein the mixing chamber and the transport tube are cylindrical and have equal diameters.

5. The gas mixing system of claim 1, wherein the porous barrier separating the mixing chamber from the transport tube comprises a circular disk in which fluid channels are formed that swirl the process gases moving from the mixing chamber to the transport tube.

6. A gas mixing apparatus used in a semiconductor processing chamber, the mixing apparatus comprising:
a gas mixing chamber comprising a gas inlet to receive process gases, a gas outlet to flow mixed gas out of the chamber, and an insert recess;
a gas mixing insert slidably fitted within the insert recess;
a fluid flow channel at least part of which is formed in the gas mixing insert, and fluidly coupled to the gas inlet, wherein the fluid flow channel includes one or more fluid separators, each comprising a first carrier channel having a channel surface separating the process gases into a plurality of gas portions flowing away from each other in the channel;
a fluid collection space formed between the gas mixing insert and the periphery of the gas mixing chamber, wherein the separated gas portions exiting the fluid separators approach from substantially opposite directions and collide with each other to combine the gas portions into the mixed gas; and
a gas transport conduit to receive the mixed gas from the gas outlet and further mix and transport the mixed gas to a blocker plate of a showerhead.

7. The gas mixing apparatus of claim 6, wherein the gas transport conduit further mixes the mixed gas being transported to the blocker plate.

8. The gas mixing apparatus of claim 6, wherein the gas mixing chamber and the gas transport conduit are substantially cylindrical and concentrically aligned with each other.

9. The gas mixing apparatus of claim 6, wherein the outlet of the gas mixing chamber comprises a porous disk at the bottom of the gas mixing chamber, wherein the disk comprises one or more turbulent flow channels that create turbulent flow in the mixed gas exiting the outlet.

10. The gas mixing apparatus of claim 6, wherein the gas mixing insert has a top section with a first diameter and a second section with a second diameter smaller than the first diameter and concentrically aligned with the top section.

11. The gas mixing apparatus of claim 10, wherein the top and second sections of the gas mixing insert are both cylindrically shaped.

12. The gas mixing apparatus of claim 10, wherein the second section of the gas mixing insert extends into the gas mixing chamber.

13. The gas mixing apparatus of claim 10, wherein the second section comprises sidewalls that form an annular shaped portion of the fluid collection space with the opposite facing periphery of the gas mixing chamber.

14. The gas mixing apparatus of claim 10, wherein the gas inlet and the fluid flow channel are connected at the top section of the gas mixing insert.

15. A gas swirl mixing device used in a semiconductor processing chamber, the mixing device comprising:
a transport plate having a plurality of holes with a first angle to guide a mixture of process gases to flow through the holes toward a first direction;
a transport tube having a plurality of holes with a second angle different from the first angle near bottom of the transport tube, wherein the holes guide the mixture to flow toward a second direction, and wherein the second direction is opposite to the first direction; and
a mixing chamber concentrically aligned with the transport tube, wherein the plate is coupled to the transport tube that is coupled to the mixing chamber to prevent a secondary process gas path; and
a blocker plate positioned below the mixing chamber and the transport tube.

16. The gas swirl mixing device of claim 15, wherein:
the first direction is clockwise; and
the second direction is counter clockwise.

17. The gas swirl mixing device of claim 15, wherein:
the first direction is counter clockwise; and
the second direction is clockwise.

18. The gas swirl mixing device of claim 15, wherein the transport plate, the transport tube and the mixing chamber comprise a metal.

19. The gas swirl mixing device of claim 18, wherein the metal comprises aluminum.

20. The gas swirl mixing device of claim 1, wherein the transport plate is cylindrically shaped with a first diameter.

21. The gas swirl mixing device of claim 1, wherein the transport tube comprises a cylindrical tube having a second diameter and a collared end having a third diameter, the collared end being on top of the cylindrical tube.

22. The gas swirl mixing device of claim 21, wherein the third diameter of the collared end of the transport tube substantially equals to the first diameter of the transport plate.

23. The gas swirl mixing device of claim 22, wherein the mixing chamber is cylindrical with a fourth diameter of a lower section and a fifth diameter of an upper section, wherein:
the fourth diameter substantially equal to the second diameter of the transport tube;
the fifth diameter is substantially equal to the third diameter of the collared end of the transport tube; and
the fourth diameter is smaller than the fifth.

24. The gas swirl mixing device of claim 1, wherein the blocker plate comprises part of a gas showerhead that also includes a faceplate below the blocker plate.

25. A chamber system for semiconductor processing, the system comprising:
a processing chamber;
a first substrate supporting member to support a first substrate within the processing chamber;
a second substrate supporting member to support a second substrate, the second substrate supporting member being positioned near the first substrate supporting member within the processing chamber;
a first swirl mixing device being located above the first substrate supporting member for providing mixed flow of process gases toward the first substrate;
a second swirl mixing device located above the second substrate supporting member for providing mixed flow of process gases toward the second substrate; wherein a first flow direction generated from a first transport tube of the first swirling mixing device is opposite to a second flow direction generated from a second transport tube of the second swirling mixing device.

26. The chamber system of claim 25, wherein the first flow direction is counter clockwise, and the second flow direction is clockwise.

27. The chamber system of claim 25, wherein the first flow direction is clockwise, and the second flow direction is counter clockwise.

28. The chamber system of claim 25, the system further comprising a flow splitter for balancing flow toward the first substrate and the second substrate, wherein the flow splitter comprises:
a gas source;
a first micrometer coupled to a first valve for gas flow toward the first substrate;
a second micrometer coupled to a second valve for gas flow toward the second substrate;
a first step motor coupled to the first micrometer for adjusting the first micrometer;
a second step motor coupled to the second micrometer for adjusting the second micrometer; and
a control system for regulating the first step motor and the second step motor to control the gas flow toward the first substrate and the second substrate.

29. The chamber system of claim 28, the system further comprising a remote plasma source being coupled to the first substrate and the second substrate for cleaning.

30. The chamber system of claim 25, the system further comprising a dual-pressure heater lift device that comprises:
a heater positioned below at least one of the first substrate supporting member or the second substrate supporting member;
a cantilever coupled to lift the heater;
a main frame coupled to the cantilever;
a slider coupled to the main frame for adjusting spacing between the heater and a showerhead, the showerhead is below each of the swirling mixing devices; and
a pneumatic cylinder coupled to the cantilever for providing compressed dry air flow to lift the cantilever.

31. The chamber system of claim 25, wherein the first gas swirl mixing comprising:
a transport plate having a plurality of holes with a first angle to guide a mixture of process gases to flow through the holes toward the second flow direction;
a transport tube having a plurality of holes with a second angle near bottom of the transport tube, wherein the holes guide the mixture to flow toward the first flow direction, wherein the second angle is different from the first angle;
a mixing chamber concentrically aligned with the transport tube, wherein the plate is coupled to the transport tube that is coupled to the mixing chamber to prevent a secondary process gas path; and
a blocker plate.

32. The chamber system of claim 30, wherein the second gas swirl mixing comprising:
a transport plate having a plurality of holes with a third angle to guide a mixture of process gases to flow through the holes toward the first flow direction;
a transport tube having a plurality of holes with a fourth angle near bottom of the transport tube, wherein the holes guide the mixture to flow toward the second flow direction, wherein the third angle is different from the fourth angle;
a mixing chamber concentrically aligned with the transport tube, wherein the plate is coupled to the transport tube that is coupled to the mixing chamber to prevent a secondary process gas path; and
a blocker plate.

33. The chamber system of claim 31, wherein:
the first flow direction is clockwise; and
the second flow direction is counter clockwise.

34. The chamber system of claim 31, wherein:
the first flow direction is counter clockwise; and
the second flow direction is clockwise.
